(19) United States
(12) Patent Application Publication
(10) Pub. No.: US 2006/0284275 A1
(43) Pub. Date: Dec. 21, 2006

(54) Optical sensor element and sensor array

(76) Inventors: Peter Deimel, Langenpreising (DE); Ulrich Prechtel, Muenchen (DE)

Correspondence Address: AKERMAN SENTERFITT, P.O. BOX 3188, WEST PALM BEACH, FL, 33402-3188, US

(21) Appl. No.: 10/560,498

(22) PCT Filed: Jun. 9, 2004
(86) PCT No.: PCT/EP04/06247

§ 371 Date: Jul. 12, 2006

(30) Foreign Application Priority Data
Jun. 11, 2003 (DE) 103 26 640.2

(51) Int. Cl. H01L 31/0232

(52) U.S. Cl. 257/432

(57) ABSTRACT

The invention relates to an optical sensor element (10) which comprises, in a semiconductor substrate (1), a light-sensitive region (18) in which charge carriers can be released by irradiation, and two doped regions (15, 16) for receiving the charge carriers released in the light-sensitive region (18). The invention is characterized in that electrodes (13, 14) for generating a field gradient in the light-sensitive region (18) are insulated from the light-sensitive region (18) and are disposed in trenches formed in the surface of the substrate (1).

### CROSS REFERENCE TO RELATED APPLICATION

This application is a national stage of PCT/EP2004/006247 filed Jun. 9, 2004 and based upon DE 103 26 640.2 filed Jun. 11, 2003 and upon DE 103 40 906.8 filed Sep. 2, 2003 under the International Convention.

### BACKGROUND OF THE INVENTION

1. Field of the Invention

The present invention concerns an optical sensor element in which a light sensitive area is formed in a semiconductor substrate in which charge carriers can be released upon irradiation, and in which two doped zones are formed for receiving the charge carriers released in the light sensitive area, as well as electrodes for generating a field gradient in the light sensitive region insulated from the light sensitive region.

2. Related Art of the Invention

Conventional sensor elements of this type have the design shown schematically in FIG. 1. FIG. 1 shows a section through a semiconductor substrate 1, in which doping zones 2, 3 are formed by diffusion or by implanting of foreign atoms. A light transmissive oxide layer 4 covers respectively a part of the doping zones 2, 3 as well as an intermediate substrate area with intrinsic conductivity. Two light transmissive electrodes 5, 6 are provided upon the oxide layer 4. The structure is similar to that of a conventional MOSFET, of which the gate is divided into two parts corresponding to the two electrodes 5, 6 by a narrow window 7.

Light penetrates through the electrodes 5, 6 and the there-between lying window 7, and through the oxide layer 4, into the semiconductor substrate 1 and produces a pair of charge carriers. The electrodes 5, 6 are transparent in order to be able to use the entire substrate surface between the doping zones 2, 3 for light absorption.

The electrodes 5, 6 are respectively alternatingly connected to a potential, which brings about a potential gradient in the area of the semiconductor substrate 1 lying between the electrodes 5, 6, which depending upon polarity shovels or pushes the charge carriers to one of the two doped zones 2, 3. Charge carriers of the suitable type, which arrive at one of the doping zones 2 or 3, produce therewith a photovoltaic current.

The usefulness of this type of sensor element lies in particular in its suitability for carrying out an optical distance measuring process. For this, a light source such as for example a laser diode with a constant signal is modulated on-off, which lies adjacent or influences also one of the electrodes 5, 6, in order to produce between them a potential gradient with alternating direction. The laser diode beams the light upon an object, of which the distance is to be measured, and light reflected from the object impinges upon the electrodes 5, 6 and/or the window 7 and produces charge carrier pairs in the there-under lying semiconductor material. If the distance of the object is zero, then no phase difference is exhibited between the light impinging upon the window 7 and the signal impinging upon for example the electrode 5; in every case when the light impinges upon the window 7, a potential gradient exists at the electrodes 5 which discharges or dissipates the charge carriers produced in the substrate to the doping zone 2. In the time intervals, in which the direction of the potential gradient is reversed and the charge carrier is provided to the doping zone 3, no light falls upon the window 7, so that in the doping zone 2 a maximal photovoltaic current and in the doping zone 3 no photovoltaic current is detected. With increasing distance of the object to be detected the delay-contingent phase displacement between the signal reaching the electrodes and the light reaching the window 7 is increasingly large, and from the relationship of the photovoltaic current tapped at the doping zones 2, 3 the distance of the object can be deduced.

One problem with the known structure according to FIG. 1 is that the light penetrates several micrometer deep into the silicon semiconductor substrate 1 (approximately 20 μm at a wavelength of 850 nm), that however the space charge zone and therewith the field gradient, which is produced in the substrate 1 by the counter phase of the potential adjacent the electrodes 5, 6, and which is necessary in order to allow the charge carriers to migrate to one of the doping zones 2, 3, exhibits a, compared thereto, substantially smaller penetration depth. This means, that only those charge carriers which are produced in the space charge zone close to the surface of the semiconductor substrate 1 and in a close distance from the electrodes 5, 6 are captured and conducted or channeled into the doping zones with good effectivity; a large part of the produced charge carriers is produced however in deeper regions of the substrate 1 outside of the space charge zone, where there is no potential gradient. In these charge carriers the probability is great that they do not arrive at any doping zone, or, as the case may be, by thermal diffusion reach a doping zone only after the potential gradient has reversed its direction. The distance information contained in these charge carriers thus becomes lost.

Besides this, it is to be assumed that only a small part of the surface of the substrate is effective for detection of light. The arrangement of the electrodes 5, 6 at the surface of the substrate leads to a strengthening of the electrical field at the edges of the electrodes facing each other. The electrodes themselves shield large parts of the substrate 1 against the electrical field of the potential gradient, so that charge carriers from there likewise arrive at one of the doping zones 2, 3 slowly by thermal diffusion.

### SUMMARY OF THE INVENTION

It is the task of the present invention to provide a sensor element of the above defined type, which exhibits a high sensitivity.

The task is solved by a sensor element. In accordance with the invention the insulated electrodes are provided in grooves formed in the surface of the substrate, they are in a condition to produce a drift in the charge carrier driving electrical field between adjacent grooves, which penetrates into substantial depths into the substrate and also detects charge carriers produced in the regions of the substrate at a distance from the surface and rapidly conducts these to one of the doping zones. The arrangement of the electrodes prevents a local super-elevation of the potential gradient; a shielding due to groove formation can be avoided. Besides this, on the basis of the arrangement of the electrodes a high percentage of the substrate surface is utilizable for signal generation. In the ideal case the electrical field extends from one groove to the other, that is, the potential gradient between the grooves is sufficient to extract nearly all produced charge carriers out of the space charge zone.

Each doping zone should usefully contact an isolation layer of one of the insulated electrodes, so that, when a conductive channel is formed in the insulation layer by the extraction potential adjacent to one of the insulated electrodes, this channel has contact with the doping zone and the charge carriers collected in the channel can be conducted to the doping zone without loss. Since, in contrast to the conventional structures, the channels in the inventive structure are oriented practically perpendicularly to the desired drift direction, they do not significantly shield the areas of the semiconductor substrate lying between two electrodes against the electrical field. Thus the total semiconductor mass between the two electrodes contributes to the sensitivity of the sensor element.

When the depth of the groove is greater than the thickness of the doping zones, the doping zones can also be provided with charge carriers formed in the electrode forming channels which are produced in deep zones of the semiconductor substrate below the doping zones. Since the thickness of the doping zones in general is much smaller than the penetration depth of the light, even the semiconductor material below the doping zone can contribute to the sensitivity of the sensor element.

The preferred depth of the grooves is between 5 and 40 μm, preferably between 12 and 25 μm. In general one selects deeper grooves according to the greater the penetration depth of the light to be measured is in the semiconductor substrate 1.

In order to achieve good utilization of the substrate surface, preferably respectively two sensor elements adjacent in a first direction are provided on both sides of a common insulated electrode. Therein doping zones bordering the common insulated electrode of the two sensor elements can be connected electrically conductive. Two sensor elements with conductive joined doping zones are preferably joined respectively into a pixel, wherein one pixel may include more than two sensor elements.

In order to provide a locationally resolving sensor arrangement, at least individual pairs of sensor elements should exist, in which the common insulated electrode adjacent doping zones of the two sensor elements are electrically insulated from each other, so that the photovoltaic current captured in the two doping zones can be processed separately from each other.

One such insulation of doping zones lying opposite from each other on both sides of an insulated electrode is for example achieved thereby, that the insulated electrode lying between them exhibits on the floor of its groove a thicker insulating layer than on its side walls. Thereby the establishment of a conductive channel across the floor of the groove is reliably prevented, which otherwise could provide a conductive connection between the doping zones.

According to a different embodiment two adjacent sensor elements associated with different pixels do not have a common insulated electrode, but rather a zone is formed between two such electrodes of the adjacent sensor elements insulating the two electrodes from each other. In one such insulating zone this could be for example the semiconductor substrate itself, if for example the two electrodes are respectively provided in a groove.

The charges tapped from the doping zones are stored in two condensers. From the differential of the charges between these two condensers the distance of an object imaged on the pixels can be determined. In order to save substrate surface, these condensers are, just like the insulated electrodes, preferably provided in the grooves, so that their plates are oriented perpendicular to the substrate surface.

Further characteristics and advantages of the invention are produced from the following description of illustrative examples with reference to the associated figures.

### BRIEF DESCRIPTION OF THE DRAWINGS

There is shown:

FIG. 1 as already discussed, a section through a semiconductor substrate of a conventional sensor element;

FIG. 2 partially in section, partially in perspective view upon the surface, of an inventive sensor element;

FIG. 3 a top view upon a pixel of a location resolving sensor array, formed from multiple sensor elements shown in FIG. 2;

FIG. 4 a top view upon multiple pixels of a second location resolving sensor array;

FIG. 5 a schematic section through a sensor element according to a second embodiment of the invention;

FIG. 6 a further example of a sensor array;

FIG. 7 partially in section, partially in perspective view on the surface of an inventive sensor element with metal semiconductor structure and Schottky barrier; and

FIG. 8 multiple sensor elements with diffused in p⁺-contact.

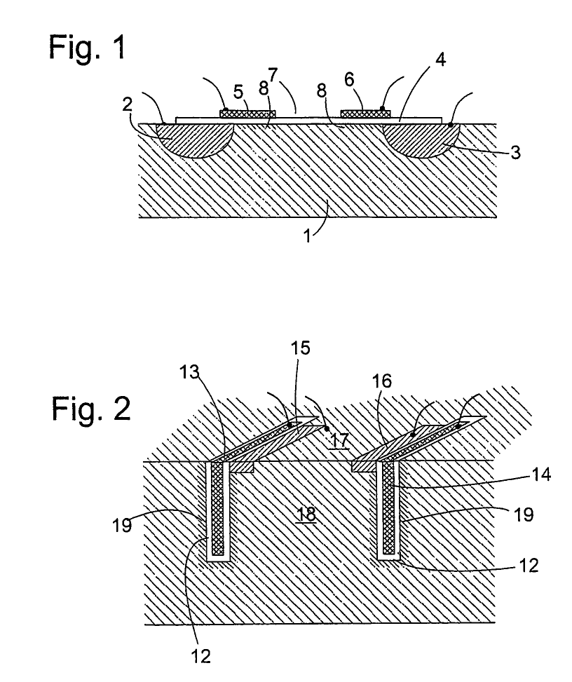

### DETAILED DESCRIPTION OF THE INVENTION

FIG. 2 shows an individual inventive sensor element 10. It includes two parallel grooves 11 anisotropically etched in a silicone substrate 1, which subsequent to etching was surface oxidized, in order to form an insulating oxide layer 12, and which were subsequently filled with electrically conductive material such as metal or highly doped silicon, in order to form electrodes 13, 14 insulated against the substrate 1. The electrodes 13, 14 lie opposite to each other in the manner of parallel plates of a condenser. The depth of the grooves 11 is typically approximately 25 μm, their length is substantially freely selectable and can, depending upon the size of the pixel formed by one or more sensor elements 10 lie for example in the range of 20 to 200 μm.

Between the two electrodes 13, 14 and respectively in contact with the oxide layer 12 of one of them are formed two doping zones 15, 16. The thickness of the doping zones 15, 16 may be several hundred nanometer and is therewith significantly smaller than the penetration depth of the light in the semiconductor substrate 1, so that not only light, which impinges upon an undoped surface area 17 between the zones 15, 16, but rather also light, which penetrates through the doping zones 15, 16 into the sensitive area 18 of the substrate lying between the grooves 11 can release charge carriers. These charge carriers are stripped or drawn off to the electrodes 13 or 14 under the action of the extraction potential. If the applied extraction potential is high enough to draw charge carriers to the area of the substrate 1 adjacent the oxide layer 12 of the electrode 13 or 14, there forms in this area a channel 19, in which the charge carrier is freely moveable. Via this channel 19 the charge carriers flow to the adjacent doping zones 15 or, as the case may be, 16.

From the doping zones 15, 16 the charge carriers are discharged or drained or transferred via an ohmic contact applied thereto, for example to (not shown) collection condensers, of which the plates, just like the electrodes 13, 14, respectively, are formed by electrically conductive material, which is introduced in one of the grooves etched into the semiconductor substrate 1, electrically insulated against the substrate 1.

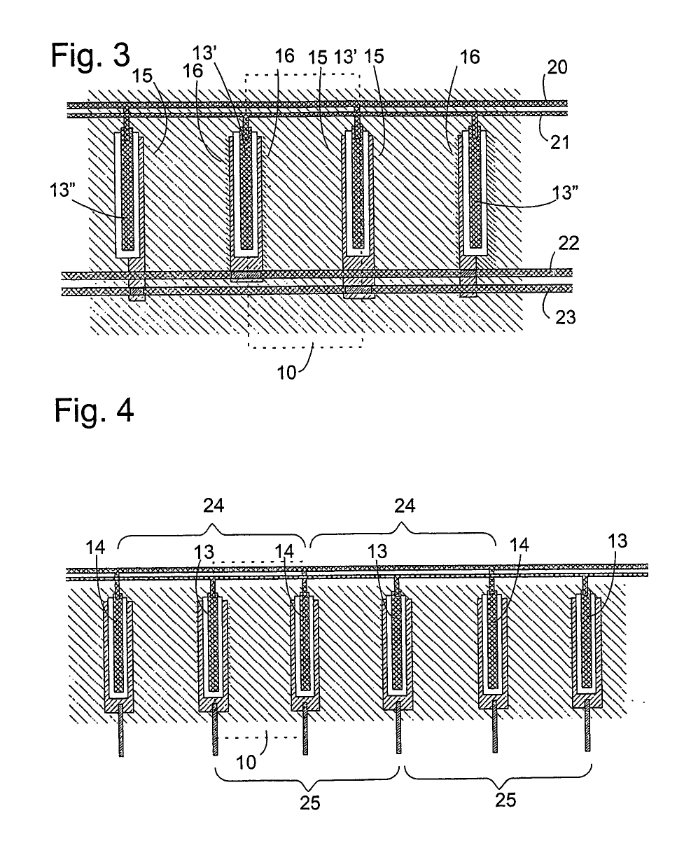

FIG. 3 shows a top view on a pixel of a sensor array, which is comprised of four sensor elements 10, as shown in FIG. 2. One individual sensor element 10 is equal to an area represented by a dashed square in FIG. 3. It provides two insulated electrodes 13, referenced in FIG. 3 with 13′, which respectively belong to two adjacent sensor elements 10 and doping zones 15, 16 extend along two longitudinal sides. The two doping zones 15, 16 on each of the electrodes 13″ are extended at the longitudinal end of the electrode 13′ and therewith fused electrically conductively with each other. Only the outer electrodes, indicated with 13″, exhibit a doping zone 15, 16 on only one of their longitudinal sides.

The electrodes 13′, 13″ are respectively alternatingly connected with two supply lines 20, 21, via which they receive the extraction potential respectively phased displaced by 180°. Correspondingly, the doping zones 15, 16 are respectively alternatingly connected with two signal conductors or lines 22, 23, via which the charge carriers flow to the collection condensers and/or other evaluations circuitry.

In the sensor array shown in FIG. 4, each individual one insulated electrode 13 or 14 surrounding doping zone 15 or 16 is provided with one of its own signal lines 24. This means that, when the electrodes 13 are connected with the extraction potential which collects the respective charge carriers from the surrounding doping zones 15 in the two sensored elements joined and respectively indicated with reference number 24 in the figure while, when the electrodes 14 receive the extraction potential, it collects these respective charge carriers from the pairs indicated with 25. Thus respectively two sensor elements 10 form one pixel, wherein the position of the pixel respectively periodically shifts by one half pixel breadth or, as the case may be, the assignment of the sensor elements 10 to a pixel varies depending upon at which electrode the extraction potential lies against or concerns. With such a sensor array very high resolution images can be produced, in particular in a half image (gray scale) mode; in order to employ these images for a locationally resolving distance measurement, there is however a greater processing investment necessary than in the case of the stationary pixels according to the embodiment of FIG. 3.

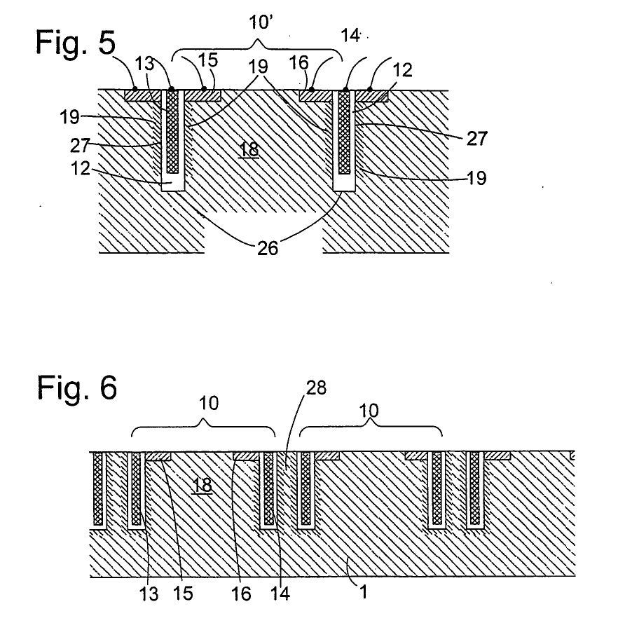

Small stationary pixels can be obtained with the embodiment according to FIG. 5. The sensor element 10′ shown in this Figure differs from the sensor element 10 of FIG. 2 therein, that the oxide layer 12 of the insulated electrodes 13, 14 respectively on the floor 26 of the groove, in which the electrodes are provided, is made significantly broader than the side flanks 27. As a consequence, the electrical field strength in the semiconductor material adjacent to the oxide layer 12 respectively at the floor 26 is smaller than at the side flanks 27. Thereby it becomes possible to apply an extraction potential at one of the electrodes 13, 14, which on the one hand is strong enough to produce two channels 19 on both sides of the electrode, but not however a channel bridging over one of these floors 26, which would short-circuit these two channels 19. Since in this embodiment the doping zones 15, 16 on both sides of an insulated electrode 13, 14 are also not connected to each other on the substrate surface, the adjacent sensor elements 10′ do not influence each other, so that each sensor element 10′ represents a pixel independent of the others.

Another possibility to decouple adjacent sensor elements in order to utilize respectively each one for themselves as a pixel is shown in FIG. 6. The individual sensor elements 10 are here identical with those of FIG. 2; however, in distinction to FIG. 3 each insulated electrode 13, 14 belongs precisely to one sensor element 10, and between adjacent to each other electrodes 13, 14 of different sensor elements 10 there is one insulating layer 28, here in the form of material of the semiconductor substrate 1.

In order to reduce the capacity of the collective sensor array, the insulating layer can also be in an additional groove, which electrically separates the grooves of the adjacent electrodes 13, 14 from each other. One such groove could surround the entire pixel and thereby contribute to the optical and electrical separation of the individual pixels from each other.

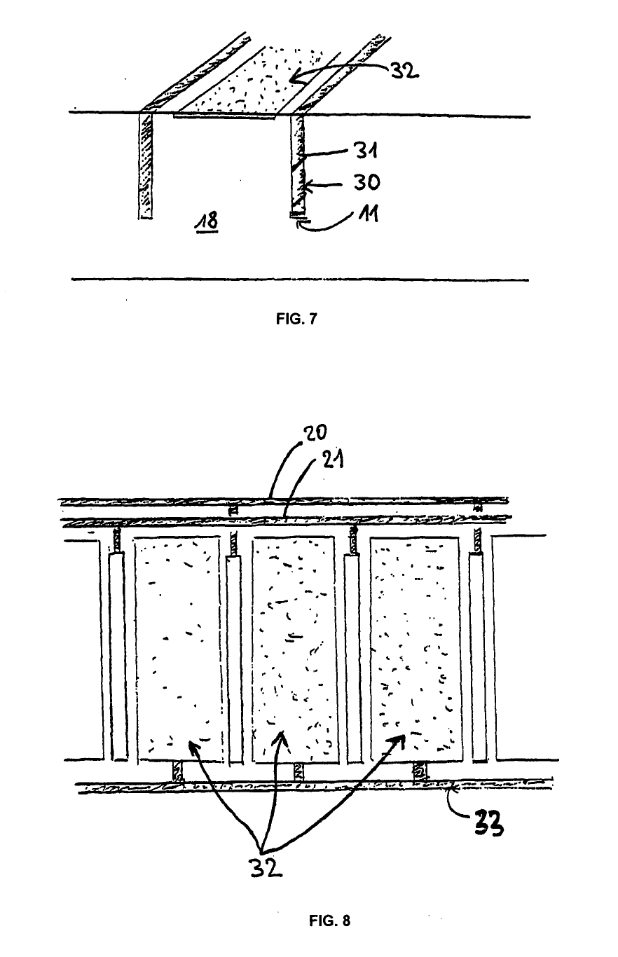

In FIG. 7 there is shown analogously to FIG. 2 and individual inventive sensor element. The sensor element shown in FIG. 7 differs from the sensor element shown in FIG. 2 therein, that in the etched groove 7, in place of a metal oxide semiconductor (MOS), a simple metal semiconductor structure 31 is introduced. In place of an oxide layer herein the grooves 11 etched in the light sensitive area 18 are, analogously to the high doped polysilicone 14, filled with a metal. Herein the oxide layer 12 shown in FIG. 2 is not present. In the groove 11 filled with the metal this is a metal semiconductor contact, which, in contrast to the silicon of the light sensitive area 18, forms Schottky barriers 30. The charge carrier produced in the silicone are phase rectified, that is, the two Schottky diodes are controlled phase-displaced by 180°, extracted via the two vertical Schottky diodes from this silicon, and conveyed or conducted onto the collection condensers. In particularly advantageous manner the sensor element herein exhibits no doping zones (15, 16). Thereby the sensor element can be produced simply, wherein less process steps are necessary.

FIG. 8 shows multiple sensor elements in accordance with the invention with p⁺-contacts 22 diffused into the upper surface of the light sensitive areas 18. By means of the broad ohmic p⁺-contacts 22 the ambient or background light, for example sunshine in the environment, can be eliminated. On the surface of the light sensitive areas 18 there are absorbed, besides the signal photons, also photons from the background light of the environment. Therein the short wave component of the background light photons exhibit only a small penetration depth into the silicon and is thus absorbed at the surface of the light sensitive areas 18. Signal photons of the nearer infrared wavelength region penetrate in contrast deeper into the silicon. By applying a reverse current to the diffused in p⁺-contacts joined with or via the conductive track 33, those charge carriers are transported away which are produced by the short wave background radiation in the vicinity of the surface of the light sensitive area 18 and do not contribute to the signal.

1. An optical sensor element (10) comprising a semiconductor substrate (1) comprising:
a light sensitive area (18) in which charge carriers are releasable upon illumination, and
two doping zones (15, 16) for receiving charge carriers released from the light sensitive area (18),
an electrode (13, 14) insulated against the light sensitive area (18) for production of a field gradient in the light sensitive area (18),
wherein the insulated electrodes (13, 14) are provided in grooves formed in the surface of the substrate (1).

2. An optical sensor element according to claim 1, wherein each doping zone (15, 16) contacts an insulation layer (12) of one of the insulated electrodes (13, 14).

3. An optical sensor element according to claim 1, wherein at each doping zone (15, 16) an ohmic contact is formed.

4. An optical sensor element according to claim 1, wherein the depth of the grooves is greater than the thickness of the doping zones (15, 16).

5. An optical sensor element according to claim 1, wherein the depth of the grooves is between 5 and 40 μm deep.

6. An optical sensor element according to claim 1, wherein each doping zone (15, 16) is associated with a collection condenser for collection of charge carriers extracted from the doping zone (15, 16).

7. An optical sensor element according to claim 6, wherein each collector condenser includes two conductive plates, which are provided in the grooves of the substrate.

8. An optical sensor element according to claim 1, wherein in place of insulated electrodes (13, 14) of metal semiconductors structures (31), built up electrodes are present, which form Schottky barriers (30) adjacent to to the light sensitive area (18).

9. An optical sensor element according to claim 8, wherein the sensor element does not include any doping zones (15, 16).

10. An optical sensor element according to claim 1, wherein on the surface of the light sensitive area (18) an ohmic p⁺-contact (32) is diffused in.

11. An optical sensor array with a plurality of sensors according to claim 1, wherein respectively two sensor elements (10) adjacent in a first direction are provided on two sides of a common insulated electrode (13′).

12. An optical sensor array according to claim 11, wherein the common insulated electrode (13′) bordering doping zones (15, 16) of the two sensor elements (10) are connected electrically conductively.

13. An optical sensor array according to claim 12, wherein the two sensor elements (10) are joined or combined into a pixel.

14. An optical sensor array according to claim 11, wherein the doping zones (15, 16) bordering the common insulated electrode (13′) of the two sensor elements (10, 10′) are insulated electrically from each other.

15. An optical sensor array according to claim 14, wherein the insulating layer (12) of one of the insulated electrodes (13, 14) is thicker at the floor (26) of its groove than at its side walls (27).

16. An optical sensor array with a plurality of sensors according to claim 1, wherein in between two adjacent insulated electrodes (13, 14) of two in a first direction adjacent sensor elements (10), a zone (28) is formed insulating the electrodes (13, 14).

17. An optical sensor array according to claim 16, wherein the insulating zone (28) is formed by the semiconductor substrate (1) or a groove.

18. An optical sensor element according to claim 5, wherein the depth of the grooves is between 2 and 25 μm deep.
